(19) United States
(12) Patent Application Publication
(10) Pub. No.: US 2025/0311314 A1
(43) Pub. Date: Oct. 2, 2025

(54) MOS TRANSISTOR STRUCTURE AND PREPARATION METHOD THEREOF

(71) Applicant: SUCCESS TECHNOLOGY LIMITED, Hong Kong (CN)

(72) Inventors: CHEN-YEN LEE, Hong Kong (CN); CHUNG YAO NI, Hong Kong (CN)

(21) Appl. No.: 18/895,316

(22) Filed: Sep. 24, 2024

(30) Foreign Application Priority Data
Apr. 1, 2024 (CN) 202410393559.9

(51) Int. Cl. H01L 29/06; H01L 29/66; H01L 29/78

(52) U.S. Cl. CPC H10D 62/10; H10D 30/025; H10D 30/63; H10D 62/124

(57) ABSTRACT

A preparation method for a metal-oxide-semiconductor (MOS) transistor structure is provided. The MOS transistor structure includes a substrate, the substrate includes an epitaxial region, a first well region, a second well region and source region, the epitaxial region includes a first surface, and a spacing between the well regions is arranged. An insulation layer is formed on a side of the substrate facing away from the first surface. A gate layer is formed on the side of the insulation layer facing away from the first surface. A reinforcement layer is formed on a side of the insulation layer facing away from the first surface, an orthographic projection of the reinforcement layer on the epitaxial region is located between the two well regions, and an electric field strength endurance of the reinforcement layer is stronger than that of the insulation layer.

### CROSS-REFERENCE TO RELATED APPLICATION

This application claims priority to Chinese patent application No. CN 202410393559.9, filed to China National Intellectual Property Administration (CNIPA) on Apr. 1, 2024, which is herein incorporated by reference in its entirety.

### TECHNICAL FIELD

The disclosure relates to the technical field of semiconductors, and particularly to a metal-oxide-semiconductor (MOS) transistor structure and a preparation method thereof.

### BACKGROUND

A metal-oxide-semiconductor (MOS) transistor structure, commonly referred to as a MOS structure, is a widely used semiconductor device. The main working principle of the MOS structure is to control the current flowing through a channel between a source region and a drain region by controlling a voltage at a gate layer, hence it is also known as a field-effect transistor (FET). Compared with silicon metal-oxide-semiconductor field-effect transistors (Si-MOSFETs) of the same power rating, silicon carbon metal-oxide-semiconductor field-effect transistors (SiC-MOSFETs) have significantly reduced on-resistance and switching losses, making them suitable for higher operating frequencies. Because an insulation layer of the SiC-MOSFET is insulative, it is used for electrical isolation, allowing the gate layer to form only an electric field without conducting direct current (DC). As a result, it is voltage-controlled, and in terms of DC electricity, the gate layer is open-circuited from the source and drain regions. Therefore, the thinner the insulation layer, the better the electric field effect, the smaller the threshold voltage, and the stronger the conduction capability under the same voltage of the gate layer. However, due to the larger electric field strength of SiC-MOSFETs, a thinner insulation layer can be easily punctured, hence existing SiC-MOSFETs cannot improve performance while maintaining their reliability.

### SUMMARY

Therefore, to overcome at least some of the defects and deficiencies in related art, the embodiments of the disclosure provide a metal-oxide-semiconductor (MOS) transistor structure and a preparation method thereof. By setting a reinforcement layer, this arrangement enhances the performance of the MOS transistor structure without increasing the on-resistance while ensuring that the insulation layer is thin, thereby increasing its reliability.

In an aspect, a preparation method for a MOS transistor structure is provided and includes steps as follows.

A substrate is provided, the substrate includes an epitaxial region, a first well region, a second well region and source region, the epitaxial region includes a first surface. The first well region and second well region are disposed at an end at an end of the epitaxial region facing away from the first surface, the first well region and the second well region are disposed oppositely to each other, and a spacing between the first well region and the second well region is arranged the source region is disposed at ends of the first well region and the second well region facing away from the first surface. Forming an insulation layer on a side of the substrate facing away from the first surface, the insulation layer includes a second surface on a side facing towards the first surface, and the insulation layer is disposed to span over the first well region, the second well region and the source region, and the insulation layer is disposed to be in contact with the first well region, the second well region, and the source region. Forming a gate layer on a side of the insulation layer facing away from the first surface. Before disposing the gate layer, forming a reinforcement layer on a side of the insulation layer facing away from the first surface. An orthographic projection of the reinforcement layer on the epitaxial region is located between the first well region and the second well region, and an electric field strength endurance of the reinforcement layer is stronger than that of the insulation layer. A doping type of the epitaxial region is the same as that of the source region, and a doping type of the first well region and a doping type of second well region are the same and different from those of the epitaxial region and source region.

In an embodiment, the forming an insulation layer on a side of the substrate facing away from the first surface includes: forming a first insulation layer on the side of the substrate facing away from the first surface. The before disposing the gate layer, forming a reinforcement layer on a side of the insulation layer facing away from the first surface includes: forming the reinforcement layer on a side of the first insulation layer facing away from the first surface. The forming an insulation layer on a side of the substrate facing away from the first surface further includes: forming a second insulation layer on the side of the substrate facing away from the first surface. The second insulation layer is disposed to cover the first insulation layer and the reinforcement layer.

In an embodiment, a thickness of the first insulation layer is the same as that of the second insulation layer.

In an embodiment, the first insulation layer is deposited on the side of the substrate facing away from the first surface, and the reinforcement layer is deposited on the side of the first insulation layer facing away from the first surface. The reinforcement layer is etched to deposit the second insulation layer on a side of the reinforcement layer facing away from the first surface and the first insulation layer facing away from the first surface.

In an embodiment, the forming a gate layer on the side of the insulation layer facing away from the first surface includes: forming the gate layer on a side of the reinforcement layer facing away from the first surface.

In an embodiment, a thickness of the insulation layer is in a range of 200-1000 angstroms.

In an embodiment, a material of the reinforcement layer is silicon nitride.

In an embodiment, a thickness of the reinforcement layer is in a range of 100-1000 angstroms.

In an embodiment, the MOS transistor structure is prepared by the above preparation method of the MOS transistor structure.

In another aspect, a MOS transistor structure is provided and includes a substrate, the substrate includes an epitaxial region, a first well region and a second well region, a source region, an insulation layer, a gate layer, a reinforcement layer. The epitaxial region includes a first surface. The first well region and second well region are disposed at an end of the epitaxial region facing away from the first surface, the first well region and the second well region are disposed oppositely to each other, and a spacing between the first well region and the second well region is arranged. The source region is disposed at ends of the first well region and the second well region facing away from the first surface. The insulation layer is disposed on a side of the substrate facing away from the first surface, the insulation layer includes a second surface on a side facing towards the first surface, and the insulation layer is disposed to span over the first well region, the second well region and the source region, and the insulation layer is disposed to be in contact with the first well region, the second well region and the source region. The gate layer is disposed on the side of the insulation layer facing away from the first surface. The reinforcement layer is disposed on a side of the insulation layer facing away from the second surface, an orthographic projection of the reinforcement layer on the epitaxial region is located between the first well region and second well region, and an electric field strength endurance of the reinforcement layer is stronger than that of the insulation layer. In addition, a doping type of the epitaxial region is the same as that of the source region, and a doping type of the first well region and a doping type of second well region are the same and different from those of the epitaxial region and source region.

As can be seen from the above, the above technical solution has at least one or more beneficial effects as follows.

The embodiment of the disclosure provides a reinforcement layer, which is disposed on a side of the insulation layer facing away from the second surface, and the orthographic projection of the reinforcement layer on the epitaxial region is located between the first well region and second well region. The electric field strength endurance of the reinforcement layer is stronger than that of the insulation layer. This arrangement ensures that that the insulation layer remains thin without increasing the conduction resistance, thereby enhancing the performance of the MOS transistor structure and increasing its reliability.

### BRIEF DESCRIPTION OF DRAWINGS

A detailed explanation of the specific embodiments of the disclosure will be provided below in conjunction with the attached drawings.

FIG. 1 illustrates a flowchart diagram of a preparation method of a metal-oxide-semiconductor (MOS) transistor structure in an embodiment of the disclosure.

FIG. 2 illustrates a schematic structural diagram of the MOS transistor structure in the embodiment of the disclosure.

FIG. 3 illustrates a schematic structural diagram of another MOS transistor structure in an embodiment of the disclosure.

FIG. 4 illustrates a schematic structural diagram of a part of the MOS transistor structure illustrated in FIG. 2 of the embodiment in the disclosure.

FIG. 5 illustrates another schematic structural diagram of a part of the MOS transistor structure illustrated in FIG. 2 of the embodiment in the disclosure.

FIG. 6 illustrates still another schematic structural diagram of a part of the MOS transistor structure illustrated in FIG. 2 of the embodiment in the disclosure.

FIG. 7 illustrates even still another schematic structural diagram of a part of the MOS transistor structure illustrated in FIG. 2 of the embodiment in the disclosure.

FIG. 8 illustrates a schematic structural diagram of a part of the MOS transistor structure illustrated in FIG. 3 of the embodiment in the disclosure.

FIG. 9 illustrates another schematic structural diagram of a part of the MOS transistor structure illustrated in FIG. 3 of the embodiment in the disclosure.

In attached drawings, description of reference signs is listed as follows:
10: MOS transistor structure; 100: substrate; 110: epitaxial region; 111: first surface; 120: first well region; 130: second well region; 140: source region; 200: insulation layer; 210: first insulation layer; 211: second surface; 220: second insulation layer; 300: gate layer; 400: reinforcement layer.

### DETAILED DESCRIPTION OF EMBODIMENTS

In order to make the above objectives, features, and advantages of the disclosure more obvious and understandable, a detailed explanation of the specific embodiments of the disclosure will be provided below in conjunction with the attached drawings.

In order to enable those skilled in the art to better understand the technical solution of the disclosure, the following will provide a clear and complete description of the technical solution in the embodiments of the disclosure in conjunction with the attached drawings. Apparently, the described embodiments are only a part of the embodiments of the disclosure, not all of them. Based on the embodiments in the disclosure, all other embodiments obtained by those skilled in the art without creative labor shall fall within the scope of protection of the disclosure.

It should be noted that the terms “first”, “second”, and so on, used in the specification, claims, and the attached drawings of the disclosure are intended to distinguish similar elements and are not intended to describe a specific sequence or order. It should be understood that such terms, when used, are interchangeable in appropriate circumstances so that the embodiments of the disclosure described here can be carried out in orders other than those illustrated or described here. Furthermore, the terms “include” and “contain” and their grammatical variations are intended to cover non-exclusive inclusion, meaning that a process, a method, a system, a product, or a device that includes a series of steps or elements is not limited to those clearly listed steps or elements but may include other steps or elements that are not clearly listed or are inherent to the process, the method, the product, or the device.

It should also be noted that the division of multiple embodiments in the disclosure is only for the convenience of description and should not constitute special limitations. The features in various embodiments can be combined and referenced to each other without contradiction.

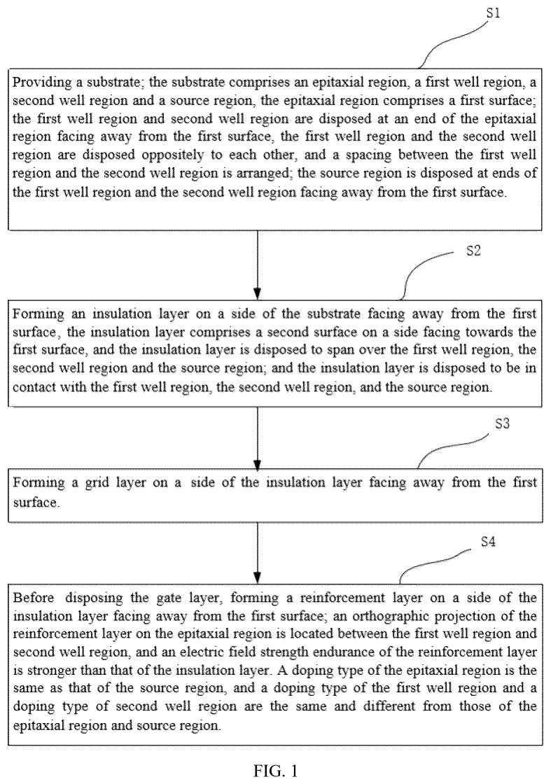

As shown in FIG. 1, a preparation method of a metal-oxide-semiconductor (MOS) transistor structure is provided and includes steps as follows.

S1: a substrate 100 is provided. The substrate 100 includes an epitaxial region 110, a first well region 120, a second well region 130 and a source region 140. The epitaxial region 110 includes a first surface 111. The first well region 120 and second well region 130 are disposed at an end of the epitaxial region 110 facing away from the first surface 111, the first well 120 region and the second well region 130 are disposed oppositely to each other, and a spacing between the first well region 120 and the second well region 130 is arranged. The source region 140 is disposed at ends of the first well region 120 and the second well region 130 facing away from the first surface 111.

S2: an insulation layer 200 is formed on a side of the substrate 100 facing away from the first surface 111. The insulation layer 200 includes a second surface 211 on a side facing towards the first surface 111, and the insulation layer 200 is disposed to span over the first well region 120, the second well region 130 and the source region 140, and the insulation layer 200 is disposed to be in contact with the first well region 120, the second well region 130 and the source region 140.

S3: a gate layer 300 is formed on a side of the insulation layer 200 facing away from the first surface 111.

S4: before forming the gate layer 300, a reinforcement layer 400 is formed on a side of the insulation layer 200 facing away from the first surface 111. An orthographic projection of the reinforcement layer 400 on the epitaxial region 110 is located between the first well region 120 and the second well region 130, and an electric field strength endurance of the reinforcement layer 400 is stronger than that of the insulation layer 200. In addition, a doping type of the epitaxial region 110 is the same as that of the source region 140, and a doping type of the first well region 120 and a doping type of second well region 130 are the same and different from those of the epitaxial region 110 and the source region 140.

In the embodiment, the reinforcement layer 400 is provided, which is disposed on a side of the insulation layer 200 facing away from the second surface 211, and the orthographic projection of the reinforcement layer 400 on the epitaxial region 110 is located between the first well region 120 and the second well region 130. The electric field strength endurance of the reinforcement layer 400 is stronger than that of the insulation layer 200. This arrangement ensures that the insulation layer 200 remains thin without increasing the conduction resistance, thereby enhancing the overall electric field strength endurance, and thus improving the performance of the MOS transistor structure 10 and increasing its reliability.

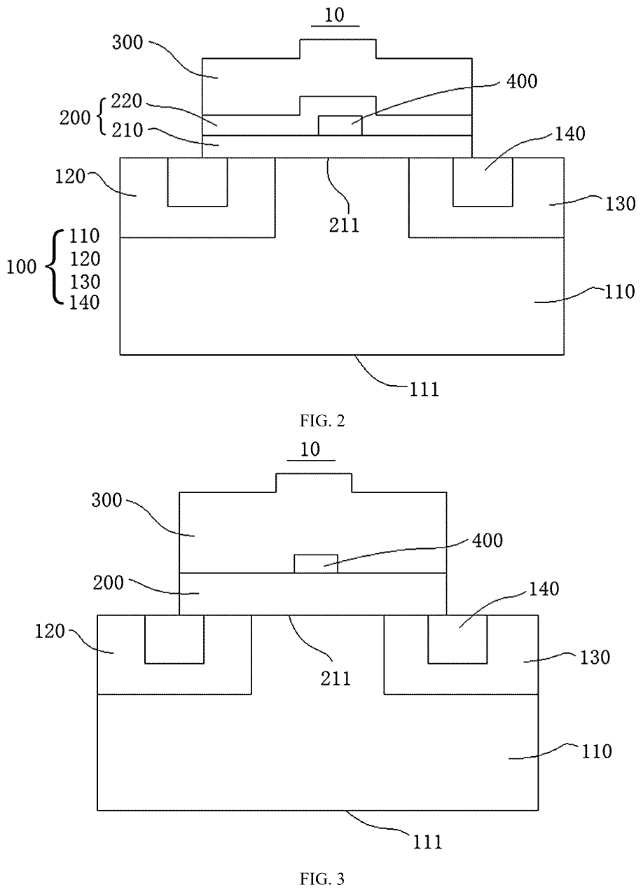

In the embodiment, as show in FIGS. 2-3, the doping type of the epitaxial region is different from the doping type of the first well region 120 and the second well region 130. For example, when the doping type of the first well region 120 and the second well region 130 is P-type, that is, the first well region 120 and the second well region 130 are P-type well regions (also called PW), the doping type of the epitaxial region 110 is N-type, that is, the epitaxial region 110 is an N-type epitaxial region (also called N-EPI). In the embodiment, taking the N-type epitaxial region as an example, the source region 140 is a heavily doped N-type region, and a doping concentration of nitrogen atoms in the source region 140 is about 10¹⁹ per cubic centimeter.

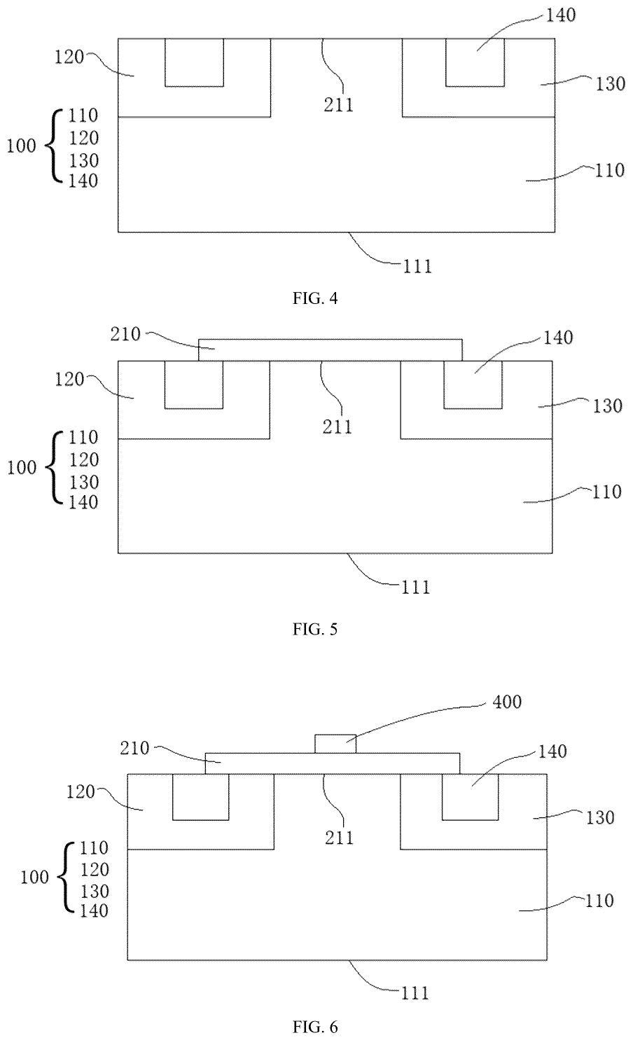

In an embodiment, as shown in FIG. 4, a shape of the substrate is a rectangular shape. For example, the epitaxial region 110 is formed as a convex structure. On two sides of a protruding structure near a convex surface of the epitaxial region 110, there are a first placement space and a second placement space. The first well region 120 and the second well region 130 are respectively formed within the first placement space and the second placement space. The first well region 120 and the second well region 130 are flush with a side of the epitaxial region 110 near the convex surface of the epitaxial region 110, meaning that the first well region 120, the second well region 130, and the epitaxial region 110 are overall formed into the rectangular shape. The source region 140 is formed in two places, each within the first well region 120 and the second well region 130, respectively. The source region 140 at the two places is formed inside the first well region 120 and the second well region 130, and the first well region 120 and the second well region 130 are disposed around the source region 140 at the two places, respectively. The side of the source region 140 near the convex surface of the epitaxial region 110 is aligned with the first well region 120 and the second well region 130. That is, the epitaxial region 110, the first well region 120, the second well region 130, and the source region 140 are all on the same horizontal level on the side near the convex surface of the epitaxial region 110.

In an embodiment, as shown in FIG. 2, the step 2 specifically includes step 21: a first insulation layer 210 is formed on the side of the substrate facing away from the first surface. The step 4 includes step 41: the reinforcement layer 400 is formed on a side of the first insulation layer 210 facing away from the first surface 111. The step 2 further includes step 22: a second insulation layer 220 is formed on a side of the reinforcement layer 400 facing away from the first surface 111. Specifically, the first insulation layer 210 is deposited on the side of the substrate 100 facing away from the first surface 111, and the reinforcement layer 400 is deposited on the side of the first insulation layer 210 facing away from the first surface 111. The reinforcement layer 400 is etched to deposit the second insulation layer 220 on the side of the reinforcement layer 400 facing away from the first surface 111 and the first insulation layer 210 facing away from the first surface 111. The second insulation layer 220 is disposed to cover the first insulation layer 210 and the reinforcement layer 400. In the embodiment, the preparation method of the MOS transistor structure is specifically ordered as steps S1, S21, S41, S22, and S3. For example, as shown in FIGS. 4-5, the substrate 100 is first formed, and then the first insulation layer 210 is formed on the side of the substrate 100 facing away from the first surface 111. The first insulation layer 210 spans over the first well region 120, the second well region 130, and the source region 140, and is in contact with the first well region 120, the second well region 130, and the source region 140. In some embodiments, the first insulation layer 210 completely covers the convex surface of the epitaxial region 110, with an end of the first insulation layer 210 in contact with a part of the first well region 120 and a part of the source region 140 within the first well region 120, and another end in contact with a part of the second well region 130 and a part of the source region 140 within the second well region 130. The first insulation layer 210 is in electrical contact with the epitaxial region 110, the first well region 120, the second well region 130, and the source region 140. The first insulation layer 210 is formed by deposition, and a thickness of the first insulation layer 210 is in a range of 100-500 angstroms (denoted as Å). 1 Å is equal to 0.1 nanometers. The first insulation layer 210 is an oxide, such as silicon dioxide.

In addition, as shown in FIG. 6, the reinforcement layer 400 is formed on the side of the first insulation layer 210 facing away from the first surface 111. A length of the reinforcement layer 400 is a length extending from the first well region 120 towards the second well region 130, which is shorter than a length of the first insulation layer 210. The reinforcement layer 400 is disposed in a middle position of the first insulation layer 210 and is located between the first well region 120 and the second well region 130. That is, the orthographic projection of the reinforcement layer 400 on the epitaxial region 110 is located between the first well region 120 and the second well region 130. The reinforcement layer 400 is formed by depositing and etching, that is, by depositing the reinforcement layer 400 on the side of the first insulation layer 210 facing away from the first surface 111, and then etching the reinforcement layer 400. The thickness of the reinforcement layer 400 is between 100 to 1000 Å. In a specific embodiment, the thickness of the reinforcement layer 400 is between 300 to 600 Å. The material of the reinforcement layer 400, for example, is silicon nitride.

Moreover, as shown in FIG. 7, the second insulation layer 220 is formed on the side of the reinforcement layer 400 facing away from the first surface 111. The length of the second insulation layer 220 is equal to the length of the first insulation layer 210. Since the length of the reinforcement layer 400 is shorter than the length of the first insulation layer 210, a part of the second insulation layer 220 covers the reinforcement layer 400, and rest part of the second insulation layer 220 covers the first insulation layer 210. The thicknesses of the first insulation layer 210 and second insulation layer 220 are the same, meaning that the thicknesses of the part of the second insulation layer 220 that is in contact with the reinforcement layer 400 and the part of the second insulation layer 220 that is in contact with the first insulation layer 210 are the same as the thickness of the first insulation layer 210. At this time, the second insulation layer 220 with a convex structure is formed by depositing, with a thickness that is between 100 to 500 Å. Specifically, the thickness of the insulation layer 200 disposed on the side of the first well region 120, the second well region 130, and the source region 140 facing away from the first surface 111 is about 200 to 1000 Å. The total thickness of the insulation layer 200 and the reinforcement layer 400 disposed on the side of the epitaxial region 110 between the first well region 120 and the second well region 130 facing away from the first surface 111 is about 700 to 1600 Å. It can be seen that the total thickness is increased due to the addition of the reinforcement layer 400 on the side of the epitaxial region 110 facing away from the first surface 111, while the thicknesses of the insulation layer 200 on the side of the first well region 120, the second well region 130, and the source region 140 facing away from the first surface 111 remain unchanged. The second insulation layer 220 is an oxide, such as silicon dioxide. As shown in FIG. 2, the gate layer 300 is formed on the side of the second insulation layer 220 facing away from the first surface 111. For example, the gate layer 300 is in a convex structure formed by depositing. The gate layer 300 is made of polycrystalline silicon. Since the electric field strength endurance of the reinforcement layer 400 is stronger than that of the insulation layer 200, by forming the reinforcement layer 400 on the insulation layer 200, it is possible to enhance the electric field effect and the conduction capability under voltage of the same gate layer 300 without increasing the on-resistance while ensuring that the insulation layer 200 remains thin. In other words, the setting of the reinforcement layer 400 can improve the performance of the MOS transistor structure 10, thereby increasing its reliability.

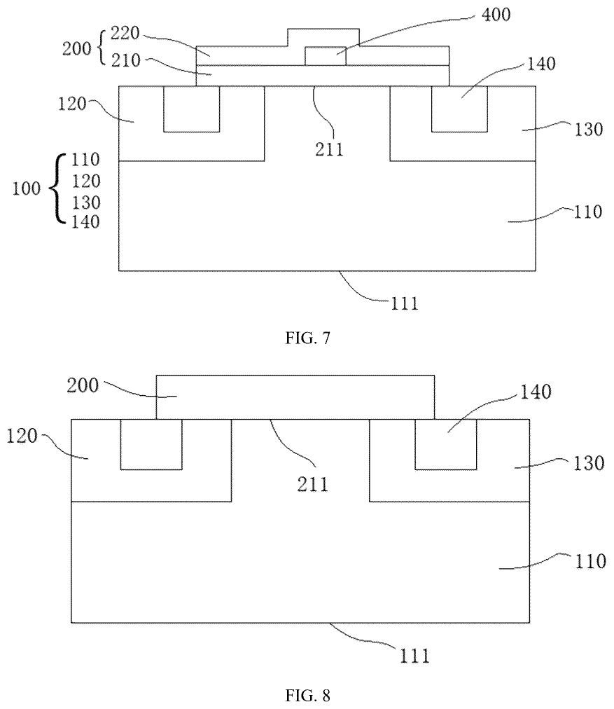

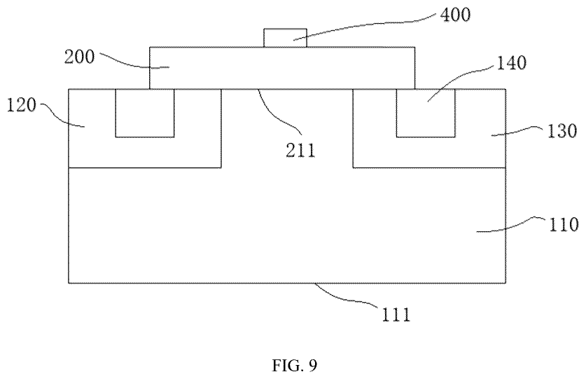

In an embodiment, as shown in FIGS. 8-9, the step 4 includes step 42: the reinforcement layer 400 is formed on a side of the insulation layer 200 facing away from the first surface 111. The step 3 specifically includes: the gate layer 300 is formed on a side of the reinforcement layer 400 facing away from the first surface 111. In the embodiment, the preparation method of the MOS transistor structure is specifically ordered as steps S1, S2, S42, S22, and S3. For example, the insulation layer 200 is formed on the side of the substrate 100 facing away from the first surface 111, the insulation layer 200 is disposed to span over the first well region 120, the second well region 130, and the source region 140, and the insulation layer 200 is disposed to be in contact with the first well region 120, the second well region 130, and the source region 140. The insulation layer 200 is formed by depositing, and the thickness of the insulation layer 200 is 200-1000 Å. The reinforcement layer 400 is formed on the side of the insulation layer 200 facing away from the first surface 111. The length of the reinforcement layer 400 is the length extending from the first well region 120 towards the second well region 130, which is shorter than the length of the insulation layer 200. The reinforcement layer 400 is disposed in the middle of the insulation layer 200 and is located between the first well region 120 and the second well region 130. That is, the orthographic projection of the reinforcement layer 400 on the epitaxial region 110 is located between the first well region 120 and the second well region 130. The reinforcement layer 400 is formed by depositing and etching, with a thickness that ranges between 100 to 1000 Å. In a specific embodiment, the thickness that ranges between 300 to 600 Å. The material used to form the reinforcement layer 400 is silicon nitride.

In addition, as shown in FIG. 3, the gate layer 300 is formed on the side of the reinforcement layer 400 facing away from the first surface 111, the length of the gate layer 300 is the same as the length of the insulation layer 200. Therefore, the length of the reinforcement layer 400 is shorter than the length of the gate layer 300. A part of the gate layer 300 is disposed to cover the reinforcement layer 400, while rest part of the gate layer 300 is disposed to cover the insulation layer 200. At this time, the gate layer 300 with a convex structure and is formed by depositing. The reinforcement layer 400 can be designed in various ways, and is not limited in this. Since the electric field strength endurance of the reinforcement layer 400 is stronger than that of the insulation layer 200, by incorporating the reinforcement layer 400 within the insulation layer 200, it is possible to enhance the electric field effect and the conduction capability under the voltage of the same gate layer 300 for the MOS transistor structure 10, without increasing the on-resistance, even while maintaining a relatively thin insulation layer 200. In other words, the inclusion of the reinforcement layer 400 can improve the performance of the MOS transistor structure 10 and thereby enhance its reliability.

In an embodiment, as shown in FIG. 2-3, the MOS transistor structure 10 is provided and is prepared by the preparation method for the MOS transistor structure mentioned above. Specifically, the MOS transistor structure 10 includes the substrate 100, the insulation layer 200, a gate layer 300 and a reinforcement layer 400.

More specifically, the substrate 100 includes the epitaxial region 110, the first well region 120, the second well region 130 and the source region 140. The epitaxial region 110 includes the first surface 111. The first well region 120 and the second well region 130 are disposed at an end of the epitaxial region 110 facing away from the first surface 111, the first well region 120 and the second well region 130 are disposed oppositely to each other, and a spacing between the first well region 120 and the second well region 130 is arranged. The source region 140 is disposed at the ends of the first well region 120 and the second well region 130 facing away from the first surface 111. The insulation layer 200 is disposed on the side of the substrate 100 facing away from the first surface 111, the insulation layer 200 includes the second surface 211 on a side facing towards the first surface 111, and the insulation layer 200 is disposed to span over the first well region 120, the second well region 130, and the source region 140, and the insulation layer 200 is disposed to be in contact with the first well region 120, the second well region 130, and the source region 140. The gate layer 300 is disposed on the side of the insulation layer 200 facing away from the first surface 111. The reinforcement layer 400 is disposed on the side of the insulation layer 200 facing away from the first surface 111, the orthographic projection of the reinforcement layer 400 on the epitaxial region 110 is located between the first well region 120 and second well region 130, and the electric field strength endurance of the reinforcement layer 400 is stronger than that of the insulation layer 200. The doping type of the epitaxial region 110 is the same as that of the source region 140, and the doping type of the first well region 120 and the doping type of second well region 130 are the same and different from those of the epitaxial region 110 and source region 140.

In the embodiment, the reinforcement layer 400 is provided, the reinforcement layer 400 is disposed on the side of the insulation layer 200 facing away from the second surface 211, the orthographic projection of the reinforcement layer 400 on the epitaxial region 110 is located between the first well region 120 and second well region 130, and an electric field strength endurance of the reinforcement layer 400 is stronger than that of the insulation layer 200. By providing the reinforcement layer 400, the setting enhances the performance of the MOS transistor structure 10 and increases its reliability without increasing the on-resistance, while ensuring that the insulation layer 200 remains thin.

The above is only specific embodiments of the disclosure and does not impose any formal limitations on the disclosure. Although the disclosure has been disclosed as the specific embodiments, they are not intended to limit the disclosure. Those skilled in the art, within the scope of the technical solution of the disclosure, may use the disclosed technical content to make some amendments or modify it into equivalent embodiments. Any simple amendments, equivalent changes, and modifications made to the above embodiments based on the technical essence of the disclosure, which are not separated from the technical solution of the disclosure, still fall within the scope of the technical solution of the disclosure.

What is claimed is:

1. A preparation method of a metal-oxide-semiconductor (MOS) transistor structure, comprising:
providing a substrate, wherein the substrate comprises an epitaxial region, a first well region, a second well region and a source region, the epitaxial region comprises a first surface; the first well region and second well region are disposed at an end of the epitaxial region facing away from the first surface, the first well region and the second well region are disposed oppositely to each other, and a spacing between the first well region and the second well region is arranged; the source region is disposed at ends of the first well region and the second well region facing away from the first surface;
forming an insulation layer on a side of the substrate facing away from the first surface, wherein the insulation layer comprises a second surface on a side facing towards the first surface, and the insulation layer is disposed to span over the first well region, the second well region and the source region; and the insulation layer is disposed to be in contact with the first well region, the second well region, and the source region;
forming a gate layer on a side of the insulation layer facing away from the first surface; and
before disposing the gate layer, forming a reinforcement layer on a side of the insulation layer facing away from the first surface; wherein an orthographic projection of the reinforcement layer on the epitaxial region is located between the first well region and second well region, and an electric field strength endurance of the reinforcement layer is stronger than that of the insulation layer; and
wherein a doping type of the epitaxial region is the same as that of the source region, and a doping type of the first well region and a doping type of second well region are the same and different from those of the epitaxial region and source region.

2. The preparation method of the MOS transistor structure as claimed in claim 1, wherein the forming an insulation layer on a side of the substrate facing away from the first surface comprises:
forming a first insulation layer on the side of the substrate facing away from the first surface;
wherein the before disposing the gate layer, forming a reinforcement layer on a side of the insulation layer facing away from the first surface comprises:
forming the reinforcement layer on a side of the first insulation layer facing away from the first surface; and
wherein the forming an insulation layer on a side of the substrate facing away from the first surface further comprises:
forming a second insulation layer on the side of the substrate facing away from the first surface, wherein the second insulation layer is disposed to cover the first insulation layer and the reinforcement layer.

3. The preparation method of the MOS transistor structure as claimed in claim 2, wherein a thickness of the first insulation layer is the same as that of the second insulation layer.

4. The preparation method of the MOS transistor structure as claimed in claim 2, wherein the first insulation layer is deposited on the side of the substrate facing away from the first surface, and the reinforcement layer is deposited on the side of the first insulation layer facing away from the first surface; the reinforcement layer is etched to deposit the second insulation layer on a side of the reinforcement layer facing away from the first surface and the first insulation layer facing away from the first surface.

5. The preparation method of the MOS transistor structure as claimed in claim 1, wherein the forming a gate layer on a side of the insulation layer facing away from the first surface comprises:
forming the gate layer on a side of the reinforcement layer facing away from the first surface.

6. The preparation method of the MOS transistor structure as claimed in claim 1, wherein a thickness of the insulation layer is in a range of 200-1000 angstroms.

7. The preparation method of the MOS transistor structure as claimed in claim 1, wherein a material of the reinforcement layer is silicon nitride.

8. The preparation method of the MOS transistor structure as claimed in claim 1, wherein a thickness of the reinforcement layer is in a range of 100-1000 angstroms.

9. A MOS transistor structure, wherein the MOS transistor structure is prepared by the preparation method of the MOS transistor structure as claimed in claim 1.

10. A MOS transistor structure, comprising:
a substrate, comprising:
an epitaxial region, having a first surface;
a first well region and a second well region, wherein the first well region and the second well region are disposed at an end of the epitaxial region facing away from the first surface, the first well region and the second well region are disposed oppositely to each other, and a spacing between the first well region and the second well region is arranged;
a source region, disposed at ends of the first well region and the second well region facing away from the first surface;
an insulation layer, wherein the insulation layer is disposed on a side of the substrate facing away from the first surface, the insulation layer comprises a second surface on a side facing towards the first surface, and the insulation layer is disposed to span over the first well region, the second well region, and the source region; and the insulation layer is disposed to be in contact with the first well region, the second well region, and the source region;
a gate layer, disposed on the side of the insulation layer facing away from the first surface; and
a reinforcement layer, wherein the reinforcement layer is disposed on a side of the insulation layer facing away from the second surface, an orthographic projection of the reinforcement layer on the epitaxial region is located between the first well region and second well region, and an electric field strength endurance of the reinforcement layer is stronger than that of the insulation layer; and
wherein a doping type of the epitaxial region is the same as that of the source region, and a doping type of the first well region and a doping type of second well region are the same and different from those of the epitaxial region and source region.
